(19) United States
(12) Patent Application Publication
(10) Pub. No.: US 2022/0056571 A1
(43) Pub. Date: Feb. 24, 2022

(54) Film Forming Method

(71) Applicant: ULVAC, INC., Kanagawa (JP)

(72) Inventors: Kengo Tsutsumi, Kanagawa (JP); Shinji Kohari, Kanagawa (JP); Kouji Sogabe, Kanagawa (JP); Toshimitsu Uehigashi, Kanagawa (JP); Takahiro Nanba, Kanagawa (JP)

(73) Assignee: ULVAC, INC., Kanagawa (JP)

(21) Appl. No.: 17/273,074

(22) PCT Filed: Jul. 9, 2020
(86) PCT No.: PCT/JP2020/026833

§ 371 Date: Mar. 3, 2021

(30) Foreign Application Priority Data
Nov. 28, 2019 (JP) 2019-215895

(51) Int. Cl. C23C 14/00; C23C 14/06; C23C 14/54

(52) U.S. Cl. CPC C23C 14/0057; C23C 14/54; C23C 14/0652

(57) ABSTRACT

A film forming method is provided in which, when a dielectric film is formed by sputtering a target, the number of particles to get adhered to the surface of a to-be-processed substrate immediately after film formation can be decreased to the extent possible without impairing the function of effectively suppressing the induction of abnormal discharging. A film forming method, according to this invention, of forming a dielectric film on a surface of a to-be-processed substrate by sputtering a target inside a vacuum chamber includes: at the time of sputtering the target, applying negative potential to the target in the form of pulses; and a frequency of applying the negative potential in the form of pulses is set to a range of 100 kHz or more and 150 kHz or below and an application time (Ton) of the negative potential is set to a range of 5 μsec or longer and 8 μsec or shorter.

### TECHNICAL FIELD

The present invention relates to a film forming method which comprises sputtering a target inside a vacuum chamber to thereby form a dielectric film on the surface of a substrate to be processed (hereinafter referred to as “to-be-processed substrate”).

### BACKGROUND ART

In the steps of manufacturing semiconductor devices, there is a step of forming a dielectric film such as a silicon nitride film and an aluminum oxide film on a surface of the to-be-processed substrate such as a silicon wafer. In the film formation of this kind of dielectric film, utilization is made of a reactive sputtering method which uses a conductive target and a reactive gas such as oxygen and nitrogen. It is normal practice at this time to apply negative potential in the form of pulses to the target so as to suppress the induction of abnormal discharging (see, e.g., patent document 1). In this kind of case, a duty ratio is set depending on a film forming time for forming a film at a predetermined film thickness on a single to-be-processed substrate, and depending on a frequency at the time of applying the negative potential in the form of pulses.

However, even if the duty ratio is set in an amount to effectively suppress the induction of abnormal discharging, it has been found that the number of particles to get adhered to the surface of the to-be-processed substrate immediately after film formation increases. Then, the inventors of this invention made strenuous studies and have come to obtain a finding in that the application time of negative potential in one cycle has an influence on the increase or decrease in the number of particles to get adhered to the surface of the to-be-processed substrate immediately after film formation.

### PRIOR ART DOCUMENTS

### Patent Documents

Patent Document 1: JP-A-2019-99907

### SUMMARY OF THE INVENTION

### Problems that the Invention is to Solve

This invention has been made based on the above-mentioned finding and has an object of providing a film forming method in which the number of particles to get adhered to the surface of the to-be-processed substrate can be decreased to the extent possible without impairing the function of effectively suppressing the induction of abnormal discharging in case a dielectric film is formed by sputtering the target.

### Means for Solving the Problems

In order to solve the above-mentioned problem, this invention is a film forming method of forming a dielectric film on a surface of a to-be-processed substrate by sputtering a target inside a vacuum chamber, comprising applying negative potential to the target in a form of pulses at a time of sputtering the target. In the film forming method: a frequency in applying the negative potential in the form of pulses is set to a range of 100 kHz or more and 150 kHz or below; and an application time of the negative potential is set to a range of 5 μsec or longer and 8 μsec or shorter. In this case, the duty ratio at the time of applying the negative potential to the target in the form of pulses shall preferably be set to 60% or more and 85% or below.

According to the above arrangement, without impairing the function of effectively suppressing the induction of abnormal discharging, the number of particles to get adhered to the surface of the to-be-processed substrate immediately after film formation can be largely decreased. By the way, if the frequency becomes smaller than 100 kHz, there will be a problem in that the time of film formation becomes long and that the resetting of the electric charges that have been charged becomes tight. On the other hand, if the frequency exceeds 150 kHz, there will be a problem in that the film forming speed lowers, and that the voltage does not follow. Further, if the application time becomes shorter than 5 μsec, the number of particles will largely increase and, on the other hand, if the application time exceeds 8 μsec, the abnormal discharging cannot effectively be restrained, and the number of particles will increase.

This invention can appropriately be applied to a case in which the target is made of silicon and, at the time of sputtering the target, a reactive gas is introduced together with a rare gas, thereby forming by reactive sputtering a silicon nitride film as a dielectric film.

### BRIEF DESCRIPTION OF THE DRAWINGS

FIG. 1 is a schematic sectional view showing the sputtering apparatus of an embodiment of this invention.

FIG. 2 is a graph showing the application time Ton of negative potential to the target.

### MODES FOR CARRYING OUT THE INVENTION

Hereinbelow, with reference to the drawings, a description will now be made of a method of forming a film according to an embodiment of this invention based on an example in which a to-be-processed substrate is a silicon wafer (hereinafter referred to as “substrate Sw”); a target is made of silicon; and a silicon nitride film as a dielectric film is formed on the surface of the substrate Sw by reactive sputtering.

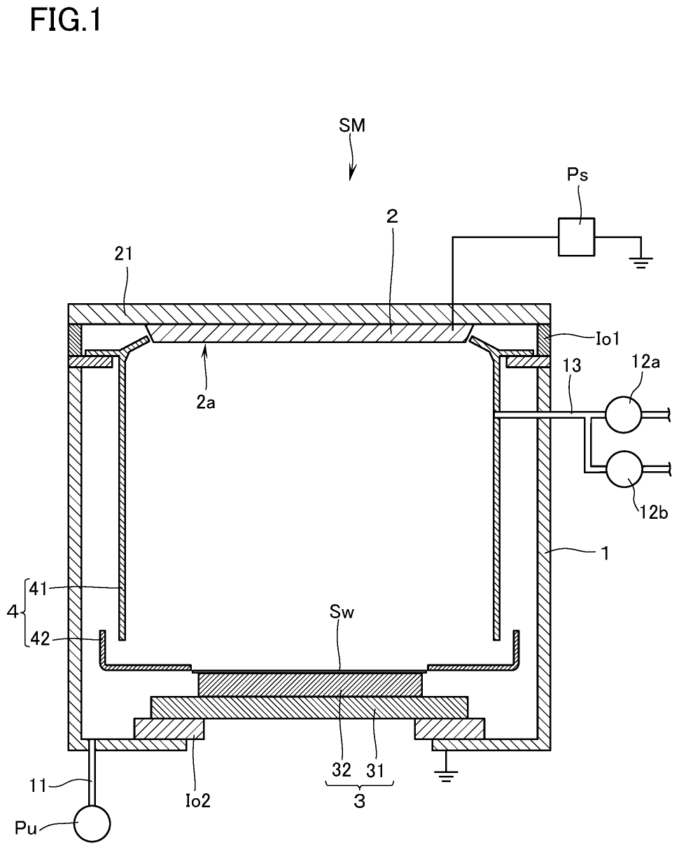

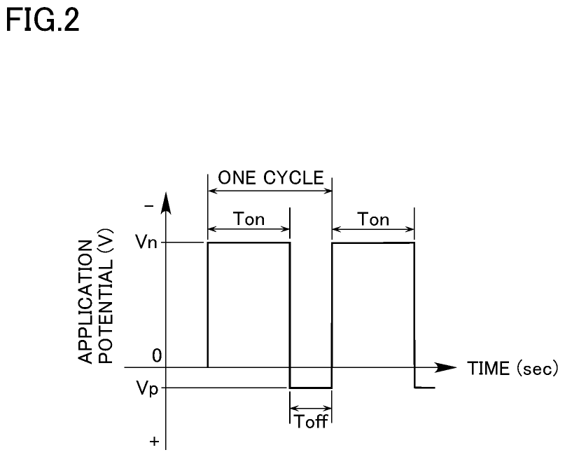

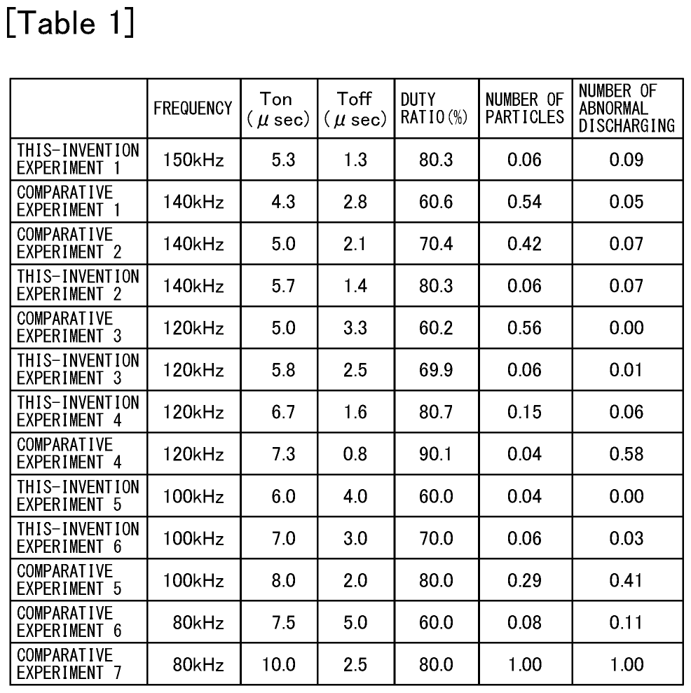

With reference to FIG. 1, reference mark SM denotes a sputtering apparatus which is capable of performing the film forming method of this embodiment. The sputtering apparatus SM is provided with a vacuum chamber 1. In the following description, the terms denoting the direction shall be understood to be based on the posture of installing the sputtering apparatus SM as shown in FIG. 1.

The vacuum chamber 1 has connected thereto an exhaust pipe 11 which is in communication with a pump unit Pu made up of a turbo-molecular pump, a rotary pump, and the like. It is thus so arranged that the vacuum chamber 1 can be evacuated down to a predetermined pressure (e.g., 1×10⁻⁵ Pa). The side wall of the vacuum chamber 1 has connected thereto a gas pipe 13 which is in communication with a gas source (not illustrated) and in which mass flow controllers 12a, 12b are interposed. It is thus so arranged that argon gas as a rare gas for electric discharging and nitrogen gas as a reactive gas can be introduced into the vacuum chamber 1 respectively at a predetermined flow rate.

At an upper part of the vacuum chamber 1 there is disposed a target 2. The target 2 is positioned on an upper part of the side wall of the vacuum chamber 1 through an insulation body Io1 in a state in which a backing plate 21 is bonded to an upper surface of the target 2 through a bonding material (not illustrated) in a posture with the sputtering surface 2a (i.e., the surface to get sputtered) facing downward. The target 2 has connected thereto an output of a pulsed DC power supply as a sputtering power supply Ps. It is thus so arranged that, at the time of sputtering the target 2, the negative potential Vn can be applied to the target 2 in the form of pulses at a predetermined frequency. As the pulsed DC power Ps, known one may be utilized, therefore further description will be omitted.

At a lower part of the vacuum chamber 1 there is disposed a stage 3 so as to lie opposite to the target 2. The stage 3 is made up of; a metal base 31 which has an annular contour and which is disposed through an insulating body Io2 provided on the lower part of the vacuum chamber 1; and a chuck plate 32 provided on the base 31. The chuck plate 32 has buried therein electrodes for the electrostatic chuck. When a predetermined voltage is applied from a chuck power supply (not illustrated) to the electrodes, the substrate Sw is arranged to be electrostatically sucked to the upper surface of the chuck plate 32 with the film forming surface facing upward.

Inside the vacuum chamber 1 there is disposed deposition preventive plates 4 which are made up of an upper deposition preventive plate 41 and a lower deposition preventive plate 42, each having a tubular contour, thereby preventing the sputtered particles and reaction products from getting adhered to the inside wall surface of the vacuum chamber 1. Although not particularly illustrated, the above-mentioned sputtering apparatus SM has known control means equipped with a microcomputer, sequencer and the like. By means of the control means, an overall control can be made over the operation of the pulse DC power supply Ps, the operations of the mass flow controllers 12a, 12b, the operation of the vacuum pump unit Pu, and the like. Description will hereinbelow be made of a method of film forming by using the above-mentioned sputtering apparatus SM.

First, after having set in position the substrate Sw on the stage 3 inside the vacuum chamber 1, the vacuum pump unit Pu is operated to thereby evacuate the vacuum chamber 1 down to a predetermined vacuum (e.g., 1×10⁻⁵ Pa). When the vacuum chamber 1 has reached the predetermined pressure, the mass flow controllers 12a, 12b are controlled to thereby introduce argon gas (10 to 100 sccm) and nitrogen gas (30 to 200 sccm) into the vacuum chamber 1 that is being evacuated at a constant evacuating speed (at this time the pressure inside the vacuum chamber attains a range of 0.01 to 30 Pa). Then, by applying negative potential Vn to the target 2 at a predetermined frequency in the form of pulses by means of the pulse DC power supply Ps, plasma atmosphere is formed inside the vacuum chamber 1. In this case, the applied power to the target 2 is set to a range of 2 kW to 15 kW. If, in this case, the power is below 2 kW, there is a problem of lowering in the productivity. If, on the other hand, the power exceeds 15 kW, there is a problem in that the damage given to the target 2 becomes larger. Further, the frequency is set to a range of 100 kHz to 150 kHz. If the frequency is below 100 kHz, the film forming time becomes longer and the resetting of the charged electric charges become tight. On the other hand, if the frequency exceeds 150 kHz, there will be a problem in a decrease in the film forming speed and in the inability to follow the voltage. According to these arrangements, the sputtering surface 2a of the target 2 gets sputtered, and the reaction products mainly of the sputtered particles splashed from the sputtering surface and the nitrogen gas get adhered to, and deposited on, the surface of the substrate Sw, thereby forming a film of silicon nitride.

Here, on the occasion of forming a silicon nitride film on the surface of the substrate Sw as described above, even if the duty ratio may be set so as to effectively suppress the induction of abnormal discharging, there is a case in which the number of particles (especially, those having sizes of 0.2 μm or more) increases, the particles being those which get adhered to the surface of the substrate Sw immediately after film forming. In this embodiment, the application time Ton of the negative potential Vn is determined to be set to a range of 5 μsec or longer and 8 μsec or shorter. According to this arrangement, without impairing the function of effectively suppressing the induction of abnormal discharging, the number of particles to get adhered to the surface of the substrate Sw immediately after film forming can be largely decreased. If the application time Ton is below 5 μsec, the number of particles largely increases. On the other hand, if the application time Ton exceeds 8 μsec, the abnormal discharging cannot effectively be suppressed. As a result, there is a problem in that the number of particles will largely increase. By the way, it is preferable to set the duty ratio (the ratio of application time Ton in one cycle) to 60% or more but 85% or below and, more preferably, to 60% or more but 81% or below. Further, during the non-application time Toff, the positive potential Vp (e.g., +50V) may be applied.

Next, in order to confirm the above-mentioned effect, the following experiments were carried out by using the above-mentioned sputtering apparatus SM. In the experiment 1 according to this invention (hereinafter referred to as “this-invention experiment 1”), a silicon wafer of Φ 300 mm (in diameter) was used as the substrate Sw. After having set in position this substrate Sw on the stage 3 inside the vacuum chamber 1, the mass flow controllers 12a, 12b were controlled to introduce into the vacuum chamber 1, 20 sccm of argon gas as the rare gas and 100 sccm of nitrogen gas as the reactive gas (at this time, the pressure inside the vacuum chamber 1 was 0.3 Pa), and negative potential Vn (−480V) was applied to the target 2 in the form of pulses. In this experiment, the frequency at the time of applying the negative potential Vn was set to 150 kHz, and the application time Ton was set to 5.3 μsec (duty ratio at this time was 80.3%). According to the above arrangement, plasma atmosphere was formed inside the vacuum chamber 1, and a silicon nitride film was formed on the surface of the substrate Sw by reactive sputtering. The number of particles that got adhered to the surface of the substrate Sw immediately after film formation was measured by a known particle counter. The measured values were normalized into 0.06 when the number of particles measured in the comparative experiment 7 to be described later was defined as 1.00 (see Table 1). It was confirmed to be smaller than a standard value (0.24) that was set considering the product yield. Further, the number of abnormal discharging during film formation was measured by a known method, and the measured values were normalized into 0.09 on the basis of the number of abnormal discharging occurred in the comparative experiment 7 to be 1.00 as described later. It has thus been confirmed that the induction of abnormal discharging was effectively suppressed.

TABLE 1

| | | | | | | NUMBER OF |
|---|---|---|---|---|---|---|
| | | Ton | Toff | DUTY | NUMBER OF | ABNORMAL |
| | FREQUENCY | (μ sec) | (μ sec) | RATIO (%) | PARTICLES | DISCHARGING |
| THIS-INVENTION | 150 kHz | 5.3 | 1.3 | 80.3 | 0.06 | 0.09 |
| EXPERIMENT 1 | | | | | | |
| COMPARATIVE | 140 kHz | 4.3 | 2.8 | 60.6 | 0.54 | 0.05 |
| EXPERIMENT 1 | | | | | | |
| COMPARATIVE | 140 kHz | 5.0 | 2.1 | 70.4 | 0.42 | 0.07 |
| EXPERIMENT 2 | | | | | | |
| THIS-INVENTION | 140 kHz | 5.7 | 1.4 | 80.3 | 0.06 | 0.07 |
| EXPERIMENT 2 | | | | | | |
| COMPARATIVE | 120 kHz | 5.0 | 3.3 | 60.2 | 0.56 | 0.00 |
| EXPERIMENT 3 | | | | | | |
| THIS-INVENTION | 120 kHz | 5.8 | 2.5 | 69.9 | 0.06 | 0.01 |
| EXPERIMENT 3 | | | | | | |
| THIS-INVENTION | 120 kHz | 6.7 | 1.6 | 80.7 | 0.15 | 0.06 |
| EXPERIMENT 4 | | | | | | |
| COMPARATIVE | 120 kHz | 7.3 | 0.8 | 90.1 | 0.04 | 0.58 |
| EXPERIMENT 4 | | | | | | |
| THIS-INVENTION | 100 kHz | 6.0 | 4.0 | 60.0 | 0.04 | 0.00 |
| EXPERIMENT 5 | | | | | | |
| THIS-INVENTION | 100 kHz | 7.0 | 3.0 | 70.0 | 0.06 | 0.03 |
| EXPERIMENT 6 | | | | | | |
| COMPARATIVE | 100 kHz | 8.0 | 2.0 | 80.0 | 0.29 | 0.41 |
| EXPERIMENT 5 | | | | | | |
| COMPARATIVE | 80 kHz | 7.5 | 5.0 | 60.0 | 0.08 | 0.11 |
| EXPERIMENT 6 | | | | | | |
| COMPARATIVE | 80 kHz | 10.0 | 2.5 | 80.0 | 1.00 | 1.00 |
| EXPERIMENT 7 | | | | | | |

In this-invention experiment 2, except for the point that the frequency was set to 140 kHz and the application time Ton was set to 5.7 μsec (duty ratio at this time was 80.3%) at the time of applying the negative potential Vn in the form of pulses, silicon nitride film was formed in a manner similar to the above-mentioned this-invention experiment 1. The number of particles to get adhered to the surface of the substrate Sw immediately after film formation was measured, and the measured values were normalized into 0.06, which has been confirmed to be smaller than the above-mentioned standard value. In addition, measurements were made of the number of abnormal discharging during film formation, and the measured values were normalized into 0.07. It has thus been confirmed that the induction of the abnormal discharging was effectively suppressed.

For the purpose of comparison with the above-mentioned this-invention experiment 2, comparative experiments 1, 2 were carried out. In these comparative experiments 1, 2, except for the point that the application times Ton were set to 4.3 μsec (duty ratio at this time was 60.6%) and 5.0 μsec (duty ratio at this time was 70.4%), respectively, that were shorter than the above-mentioned this-invention experiment 2, silicon nitride film was formed in a manner similar to the above-mentioned this-invention experiment 2. Measurements were made of the number of abnormal discharging during film formation respectively, and each of the measured values was normalized into 0.05 and 0.07. It has thus been confirmed that the induction of the abnormal discharging was effectively suppressed. However, when the number of particles to get adhered to the surface of the substrate Sw immediately after film formation were respectively measured, each of the measured values was normalized into 0.54, 0.42, respectively. They have thus been confirmed to exceed the above-mentioned standard value.

In this-invention experiment 3, except for the points that the frequency was set at 120 kHz and the application time Ton was set at 5.8 μsec (duty ratio at this time was 69.9%) at the time of applying the negative potential in the form of pulses, in the same manner as the above-mentioned this-invention experiment 1, a silicon nitride film was formed. The number of particles to get adhered to the surface of the substrate Sw immediately after film formation was measured and the measured values were normalized into 0.06. It has thus been confirmed to be smaller than the above-mentioned standard value. In addition, measurements were made of the number of abnormal discharging during film formation, and the measured values were normalized into 0.01. It has thus been confirmed that the induction of the abnormal discharging was effectively suppressed.

In this-invention experiment 4, except for the point that the application time Ton was set to 6.7 μsec (duty ratio at this time was 80.7%) that was longer than that in the above-mentioned this-invention experiment 3, in a manner similar to the above-mentioned this-invention experiment 3, silicon nitride film was formed. Measurements were made of the number of particles to get adhered to the surface of the substrate Sw immediately after film formation, and the measured values were normalized into 0.15, which has been confirmed smaller than the above-mentioned standard value. In addition, the number of abnormal discharging during film formation was measured, and the measured values were normalized into 0.06. Accordingly, it has been confirmed that the induction of abnormal discharging can be effectively suppressed.

For the purpose of comparison with the above-mentioned this-invention experiments 3, 4, comparative experiments 3, 4 were carried out. In these comparative experiments 3, 4, except for the point that the application time Ton was set to 5.0 μsec (duty ratio at this time was 60.2%) that is shorter than that in this-invention experiment 3, and was set to 7.3 μsec (the duty ratio at this time was 90.1%) that is longer than that in the above-mentioned this-invention experiment 4, silicon nitride film was formed in a manner similar to the above-mentioned this-invention experiments 3, 4. The number of abnormal discharging during film formation was respectively measured, and each of the measured values was normalized into 0.00 and 0.58. Accordingly, it has been confirmed that, while the induction of abnormal discharging was effectively suppressed in the comparative experiment 3, the induction of the abnormal discharging was not suppressed effectively in the comparative experiment 4. In addition, measurements were made of the number of particles to get adhered to the surface of the substrate Sw immediately after film formation, and each of the measured values was normalized into 0.56 and 0.04, respectively. While the above-mentioned standard value was exceeded in the comparative experiment 3, the measured value was found to be smaller than the above-mentioned standard value in the comparative experiment 4.

In this-invention experiment 5, except for the point that the frequency was set to 100 kHz, and the application time Ton was set to 6.0 μsec (duty ratio at this time was 60.0%) at the time of applying the negative potential in the form of pulses, silicon nitride film was formed in a manner similar to the above-mentioned this-invention experiment 1. Measurements were made of the number of particles to get adhered to the surface of the substrate Sw immediately after film formation, and the measured values were normalized into 0.04, which was confirmed to be smaller than the above-mentioned standard value. In addition, measurement was made of the number of abnormal discharging during film formation and the measured values were normalized into 0.00. Confirmation was made that the induction of abnormal discharging can be effectively suppressed.

In this-invention experiment 6, except for the point that the application time Ton was set to a value of 7.0 μsec (duty ratio at this time was 70.0%) that is longer than that in the above-mentioned this-invention experiment 5, silicon nitride film was formed in a manner similar to the above-mentioned this-invention experiment 5. Measurements were made of the number of particles to get adhered to the surface of the substrate Sw immediately after film formation. The measured values were normalized into 0.06, and confirmation was made that the value was smaller than the above-mentioned standard value. Further, the number of abnormal discharging during film formation was measured, and the measured values were normalized into 0.03. Confirmation was made that the induction of abnormal discharging was effectively suppressed.

For the purpose of comparison with the above-mentioned this-invention experiments 5, 6, comparative experiment 5 was carried out. In the comparative experiment 5, except for the point that the application time Ton was set to 8.0 μsec (duty ratio at this time was 80.0%) that was longer than those in this-invention experiments 5, 6, silicon nitride film was formed in a manner similar to the above-mentioned this-invention experiments 5, 6. The number of particles to get adhered to the surface of the substrate Sw immediately after film formation was measured, and the measured values were normalized into 0.29. This value has been confirmed to exceed the above-mentioned standard value. The number of abnormal discharging during film formation was measured, and the measured values were normalized into 0.41. It has thus been confirmed that the induction of the abnormal discharging could not effectively be suppressed.

In the above-mentioned comparative experiment 6, except for the point that the frequency was set to 80 kHz, and the application time Ton was set to 7.5 μsec (duty ratio at this time was 60.0%) at the time of application of the negative potential Vn in the form of pulses, silicon nitride film was formed in a manner similar to the above-mentioned this-invention experiment 1. The number of particles to get adhered to the surface of the substrate Sw immediately after film formation was measured, and the measured values were normalized into 0.08, which has been confirmed to be below the above-mentioned standard value. In addition, the number of abnormal discharging during film formation was measured, and the measured values were normalized into 0.11. It has thus been confirmed that the induction of the abnormal discharging can effectively be suppressed. However, it has been confirmed that the film formation time becomes longer and the productivity is lowered.

In the comparative experiment 7, except for the point that the application time Ton was set to 10.0 μsec (duty ratio at this time was 80.0%) which is longer than that in the above-mentioned comparative experiment 6, silicon nitride film was formed in a manner similar to the above-mentioned comparative experiment 6. The number of particles to get adhered to the surface of the substrate Sw immediately after film formation was measured, and the measured values were normalized into 1.00. This value has been confirmed to exceed the above-mentioned standard value. In addition, the number of abnormal discharging during film formation was measured, and the measured values were normalized into 1.00. It has thus been confirmed that the induction of the abnormal discharging cannot effectively be suppressed.

According to the above experiments, by setting the frequency at the time of applying the negative potential in the form of pulses to a range of 100 kHz or more and 150 kHz or below, and by setting the application time Ton of negative potential to a range of 5 μsec or longer and 8 μsec or shorter, it has been found that the number of particles to get adhered to the surface of the substrate Sw immediately after film formation can be minimized without impairing the function of effectively suppressing the induction of abnormal discharging.

Descriptions have so far been made of the embodiments of this invention, but this invention shall not be limited to the above. In the above-mentioned embodiments, descriptions were made of an example in which silicon nitride film was formed by using a target 2 made of silicon. The dielectric film, however, shall not be limited to the silicon nitride film, but this invention is applicable to the case of forming a silicon oxide film or an oxy-nitriding silicon film, or to the case of forming aluminum oxide film by using a target made of aluminum.

### EXPLANATION OF MARKS

SM sputtering apparatus
Sw substrate (substrate to be processed, also referred to as “to-be-processed substrate”)
Ton Application time of negative potential
1 vacuum chamber
2 target

1. A film forming method of forming a dielectric film on a surface of a to-be-processed substrate by sputtering a target inside a vacuum chamber, comprising applying negative potential to the target in a form of pulses at a time of sputtering the target, wherein:
a frequency in applying the negative potential in the form of pulses is set to a range of 100 kHz or more and 150 kHz or below; and
an application time of the negative potential is set to a range of 5 μsec or longer and 8 μsec or shorter.

2. The film forming method according to claim 1, wherein the target is made of silicon and, at the time of sputtering the target, a reactive gas is introduced together with a rare gas, thereby forming by reactive sputtering a silicon nitride film as a dielectric film.
